(19) United States
(12) Patent Application Publication
(10) Pub. No.: US 2023/0122167 A1
(43) Pub. Date: Apr. 20, 2023

(54) METHOD FOR CONDITIONING A PLASMA PROCESSING CHAMBER

(71) Applicant: Lam Research Corporation, Fremont, CA (US)

(72) Inventors: Neil Marshall WILSON, Sunnyvale, CA (US); Niklas ROSCHEWSKY, Lake Oswego, OR (US); Seetharaman RAMACHANDRAN, San Jose, CA (US)

(21) Appl. No.: 17/911,596

(22) PCT Filed: Mar. 10, 2021
(86) PCT No.: PCT/US2021/021743

§ 371 Date: Sep. 14, 2022

Related U.S. Application Data
(60) Provisional application No. 62/991,236, filed on Mar. 18, 2020.

(51) Int. Cl. H01J 37/32

(52) U.S. Cl. CPC H01J 37/32477; H01J 37/32862; H01J 37/32449; H01J 2237/332; H01J 2237/201; H01L 21/31116

(57) ABSTRACT

A method for processing one or more substrates in a plasma processing chamber is provided. A plurality of cycles is provided, wherein each cycle comprises providing a pre-coat process, processing at least one substrate within the plasma processing chamber, and cleaning the plasma processing chamber. The providing the pre-coat process comprises one or more cycles of depositing a silicon containing pre-coat layer and depositing a carbon containing pre-coat layer.

### CROSS-REFERENCE TO RELATED APPLICATION

This application claims the benefit of priority of U.S. Application No. 62/991,236, filed Mar. 18, 2020, which is incorporated herein by reference for all purposes.

### BACKGROUND

The disclosure relates to methods of forming semiconductor devices on a semiconductor substrate. More specifically, the disclosure relates to conditioning a chamber for the processing of substrates.

In forming semiconductor devices, plasma processing chambers may be used to process substrates. Residues are deposited within the plasma processing chambers. The residues may be removed by using a cleaning process between the processing of each substrate. In addition, plasma processing may erode components of the plasma processing chamber. Coatings may be used to protect components from erosion.

### SUMMARY

To achieve the foregoing and in accordance with the purpose of the present disclosure, a method for processing one or more substrates in a plasma processing chamber, the method is provided. A plurality of cycles is provided, wherein each cycle comprises providing a pre-coat process, processing at least one substrate within the plasma processing chamber, and cleaning the plasma processing chamber. The providing the pre-coat process comprises one or more cycles of depositing a silicon containing pre-coat layer and depositing a carbon containing pre-coat layer.

In another manifestation, a method for conditioning a semiconductor processing chamber for processing a substrate, wherein the conditioning is provided before the substrate is placed in the semiconductor processing chamber is provided. A pre-coat process is provided, wherein the pre-coat process comprises one or more cycles of depositing a silicon containing pre-coat layer and depositing a carbon containing pre-coat layer.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-D are schematic cross-sectional views of part of a component processed according to an embodiment.

FIG. 3 is a schematic view of a etch chamber that may be used in an embodiment.

FIG. 4 is a schematic view of a computer system that may be used in practicing an embodiment.

### DETAILED DESCRIPTION OF THE EMBODIMENTS

The present disclosure will now be described in detail with reference to a few embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

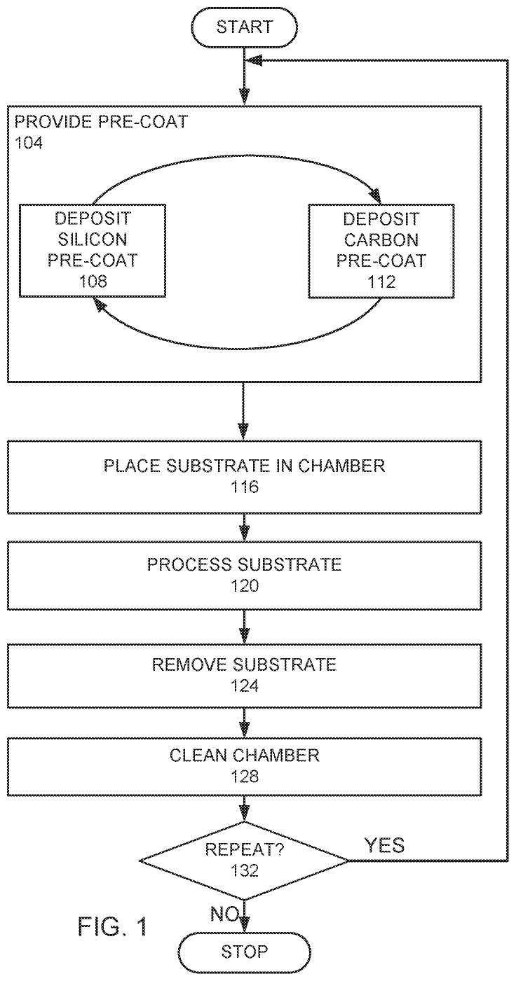

FIG. 1 is a high level flow chart of an embodiment for processing substrates. In an exemplary embodiment, in order to improve the processing uniformity of a substrate, before the substrate is placed in a plasma processing chamber, a pre-coat is formed in the plasma processing chamber (step 104). The pre-coat is formed by a pre-coat process of one or more cycles of depositing a silicon containing pre-coat (step 108) and depositing a carbon containing pre-coat (step 112). After one or more cycles, the pre-coat formation is complete (step 104).

An example recipe for depositing a silicon containing pre-coat (step 108) flows a silicon deposition gas of 100 sccm SiCl₄, 200 sccm O₂, and 300 sccm Ar into a plasma processing chamber. The silicon deposition gas is transformed into a plasma by providing 1000 watts of TCP power at 13.6 megahertz (MHz). A transformer coupled capacitive tuning (TCCT) match of 1 is provided. A chamber pressure of 10 mTorr is provided. As a result, the depositing the silicon containing pre-coat (step 108) deposits a silicon oxide based pre-coat layer.

An example recipe for depositing a carbon containing pre-coat (step 112) flows a carbon deposition gas comprising 150 sccm fluoromethane (CH₃F) and 150 sccm fluoroform (CHF₃) into a plasma processing chamber. The carbon deposition gas is transformed into a plasma by providing 1600 watts of transformer coupled plasma (TCP) power at 13.6 MHz. A transformer coupled capacitive tuning (TCCT) match of 0.5 is provided. A chamber pressure of 100 mTorr is provided. In other embodiments, the carbon deposition gas comprises other hydrocarbons, fluorocarbons, or hydrofluorocarbons.

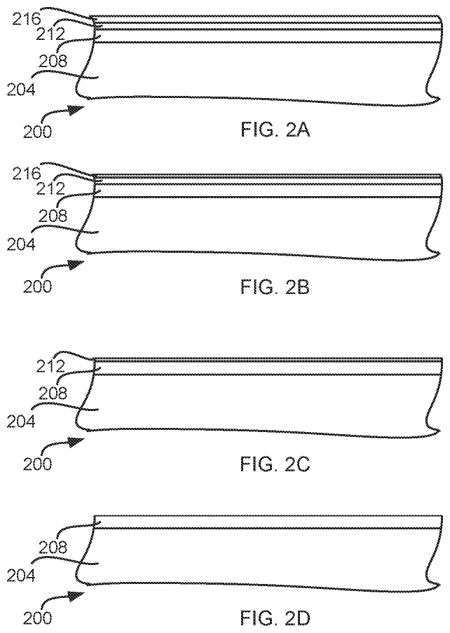

FIG. 2A is a cross-sectional view of a component 200 including a component body 204 forming part of a plasma processing chamber in an embodiment. In this embodiment, the component body 204 is made of aluminum. The aluminum may be an aluminum alloy. In other embodiments, the component body may be made of other materials, such as other metals, such as stainless steel. An yttrium oxide coating 208 is over a surface of the component body 204, providing a protective coating. A silicon containing pre-coat layer 212 is over the yttrium oxide coating 208. A carbon containing pre-coat layer 216 is over the silicon containing pre-coat layer 212. In other embodiments, additional bi-layers of silicon containing pre-coat layers 212 and carbon containing pre-coat layers 216 are over the yttrium oxide coating 208.

After the silicon containing pre-coat layer 212 and the carbon containing pre-coat layer 216 are formed over the component body 204 forming part of a plasma processing chamber, a substrate is placed in the plasma processing chamber (step 116). The substrate may be a silicon wafer. After the substrate has been placed into the plasma processing chamber, the substrate is processed (step 120). The process may be an etch process. The etch process may etch a dielectric or conductive layer. Such a process may provide an etch gas. The etch gas would be formed into a plasma. In this embodiment, a silicon containing layer is etched. The carbon containing pre-coat layer 216 resists etching during the etching of the silicon containing layer.

The carbon containing pre-coat layer 216 protects the yttrium oxide coating 208, whereas a silicon containing pre-coat layer 212 without the carbon containing pre-coat layer 216 would be more quickly etched during the etching of the silicon containing layer over the substrate and would expose the yttrium oxide coating 208 to the silicon containing layer etch.

FIG. 2B is a cross-sectional view of the component 200 after the silicon containing layer is etched. Part of the carbon containing pre-coat layer 216 has been etched away. However, since the carbon containing pre-coat layer 216 is etch resistant to the silicon containing layer etch, some of the carbon containing pre-coat layer 216 remains.

In this embodiment, after the silicon containing layer over the substrate is etched, a carbon containing layer over the substrate would be etched or stripped. In this embodiment, the carbon containing layer is an amorphous carbon mask used to pattern the silicon containing layer during the silicon containing layer etch. Without the silicon containing pre-coat layer 212, the yttrium oxide coating 208 would be damaged during the etching or stripping of the carbon containing layer over the substrate.

FIG. 2C is a cross-sectional view of the component 200 after the carbon containing layer is etched or stripped. The carbon containing pre-coat layer 216 is removed and part of the silicon containing pre-coat layer 212 has been etched away. However, since the silicon containing pre-coat layer 212 is resistant to etching during the carbon containing layer etch or strip, some of the silicon containing pre-coat layer 212 remains.

After the substrate is processed (step 120), the substrate is then removed from the plasma processing chamber (step 124). After the substrate has been removed, the interior of the plasma processing chamber is cleaned (step 128). Since in this embodiment, the substrate has been removed (step 124) and a new substrate has not been placed in the plasma processing chamber, the cleaning process is a waferless cleaning.

In this embodiment, the cleaning of the plasma processing chamber (step 128) removes the remaining silicon containing pre-coat layer 212 since the carbon containing pre-coat layer 216 has been completely etched away. In this embodiment in order to remove the remaining silicon containing pre-coat layer 212, a silicon containing pre-coat layer stripping gas is flowed into the plasma processing chamber. In this embodiment, to strip away silicon oxide, the silicon containing pre-coat layer stripping gas comprises 30 sccm to 500 sccm of nitrogen trifluoride (NF₃), and 0 sccm to 200 sccm of argon (Ar). A plasma is generated from the silicon containing pre-coat layer stripping gas. In this embodiment, this may be accomplished by providing an excitation radio frequency (RF) with a frequency of 13.6 megahertz (MHz) at 2000 watts. The plasma is maintained until the remaining silicon containing pre-coat layer 212 is removed. FIG. 2D is a cross-sectional view of the component 200 after the remaining silicon containing pre-coat layer 212 has been removed.

The cleaning of the plasma processing chamber (step 128) removes contaminants deposited during substrate processing (step 120) and strips any remaining pre-coat. After, the plasma processing chamber is cleaned (step 128), the process returns (step 132) to the step of providing a pre-coat (step 104), and the cycle is repeated. The foregoing cycle is repeated multiple times as needed or desired.

This embodiment allows for a thinner pre-coat. If only a silicon containing pre-coat is used, such as a single silicon oxide pre-coat is used, then during an etch process that etches silicon oxynitride (SiON), a thick pre-coat would be needed. This is because a process for etching SiON would significantly etch the silicon containing pre-coat. As thicker layers of SiON are etched thicker single coats of silicon containing pre-coat would be needed. If the single silicon oxide pre-coat is too thick, the throughput is decreased due to the longer time needed to deposit a thicker pre-coat and the longer time to remove the thicker pre-coat. In addition, as the silicon oxide pre-coat becomes thicker the structural stability decrease, increasing the chance that some of the silicon oxide pre-coat will flake off during processing, increasing wafer defects. In addition, if the single coat of silicon containing pre-coat is too thick, substrates may undesirably dechuck during processing. An undesirable dechuck could cause particles that may contaminate the substrate. The particles may be caused by the substrate bumping into an edge ring. In addition, an undesirable dechuck may halt processing if misalignment caused by the dechucking is significant enough to cause misalignment of the substrate on a transfer arm.

This embodiment provides two thin pre-coats of different materials, where one pre-coat is silicon containing and the other pre-coat is carbon containing. As explained above, the carbon containing pre-coat layer 216 provides improved etch resistance when etching SiON, and the silicon containing pre-coat layer 212 provides improved etch resistance when etching or stripping a carbon containing layer. As a result, a thinner overall pre-coat is required. Since in this embodiment, all of the carbon containing pre-coat layer 216 is removed, only a thin layer of the silicon containing pre-coat layer 212 needs to be cleaned away (step 128), allowing for a quick clean process.

On the other hand, the thin silicon containing pre-coat layer 212 and carbon containing pre-coat layer 216 provide sufficient protection so that the yttrium oxide coating 208 is protected and not exposed to plasma. By preventing exposure of the yttrium oxide coating 208 from plasma, the silicon containing pre-coat layer 212 and carbon containing pre-coat layer 216 prevent defects caused by particles generated from the interaction between the yttrium oxide coating 208 and plasma. In addition, the silicon containing pre-coat layer 212 and the carbon containing pre-coat layer 216 improve wafer to wafer repeatability by ensuring that chamber conditions are the same for each substrate processed. The silicon containing pre-coat layer 212 and the carbon containing pre-coat layer 216 also reduce defects by covering contaminants in the plasma processing chamber.

In another embodiment, in providing a pre-coat (step 104), a carbon containing pre-coat is first deposited (step 112) and then a silicon containing pre-coat is deposited (step 108). In such an embodiment during the processing of a substrate (step 120), an organic layer over the substrate is first etched, patterned, or stripped. Next, a silicon containing layer over the substrate is etched. The silicon containing pre-coat provides protection when the organic layer over the substrate is etched, patterned, or stripped. The silicon containing pre-coat is etched away and the carbon containing pre-coat provides protection when the silicon containing layer over the substrate is etched.

In this embodiment, in order to clean the chamber (step 128) only the remaining carbon containing pre-coat needs to be removed, since the silicon containing pre-coat was removed during the etching of the silicon containing layer over the substrate. To clean the carbon containing pre-coat, the cleaning gas comprises 40-200 sccm oxygen (O₂). A plasma is generated from the cleaning gas by providing an excitation RF at a frequency of 13.6 MHz at 1000 watts. In this embodiment, no bias is applied. The cleaning process is then stopped.

This embodiment allows the processing of a substrate where an organic layer is first processed and then a silicon containing layer is processed. In other embodiments, the substrate may have two or more alternating layers of a carbon containing layer and a silicon containing layer. In such embodiments, the providing the pre-coat (step 104) comprises at least two cycles of depositing the silicon containing pre-coat (step 108) and depositing the carbon containing pre-coat (step 112).

In various embodiments, the silicon containing pre-coat layer 212 comprises silicon oxide and is carbon free. In various embodiments, the carbon containing pre-coat layer 216 comprises at least one of a hydrofluorocarbon, a hydrocarbon, or a fluorocarbon and in addition is silicon free. In various embodiments, a blank wafer may be placed in the plasma processing chamber before the cleaning of the chamber (step 128), so that the blank wafer covers and protects a chuck during the cleaning of the chamber (step 128). In other embodiments, a blank wafer may be in the plasma processing chamber during the providing the pre-coat (step 104).

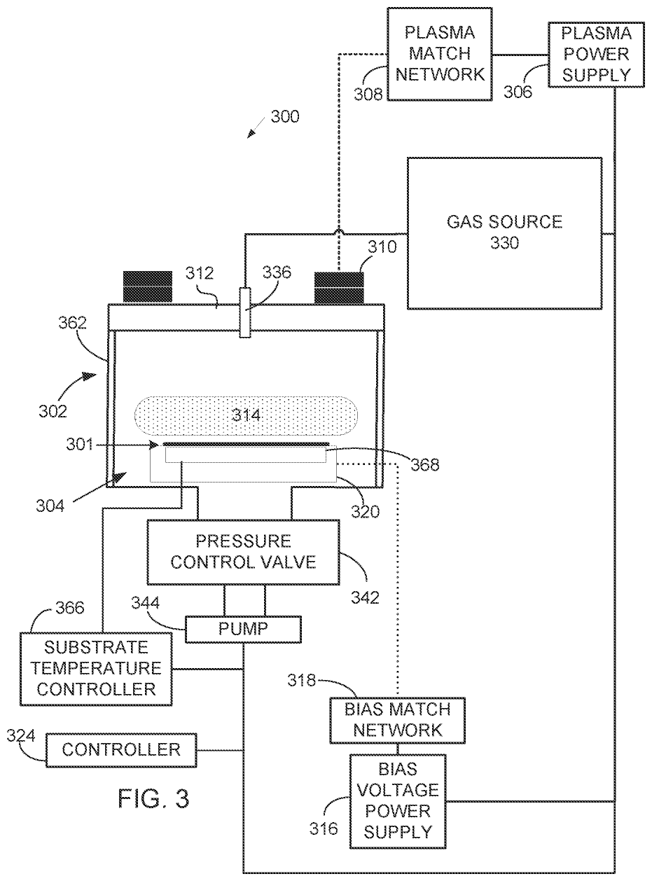

FIG. 3 schematically illustrates an example of a plasma processing system 300 that may be used in an embodiment. The plasma processing system 300 may be used to process a substrate 301 in accordance with one embodiment. The plasma processing system 300 includes a plasma reactor 302 having a plasma processing chamber 304, enclosed by a chamber wall 362. A plasma power supply 306, tuned by a plasma match network 308, supplies power to a TCP coil 310 located near a power window 312 to create a plasma 314 in the plasma processing chamber 304 by providing an inductively coupled power. The TCP coil (upper power source) 310 may be configured to produce a uniform diffusion profile within the plasma processing chamber 304. For example, the TCP coil 310 may be configured to generate a toroidal power distribution in the plasma 314. The power window 312 is provided to separate the TCP coil 310 from the plasma processing chamber 304 while allowing energy to pass from the TCP coil 310 to the plasma processing chamber 304. A wafer bias voltage power supply 316 tuned by a bias match network 318 provides power to an electrode 320 to set the bias voltage on the substrate 301. The electrode 320 provides a chuck for the substrate 301, where the electrode 320 acts as an electrostatic chuck. A substrate temperature controller 366 is controllably connected to a Peltier heater/cooler 368. A controller 324 controls the plasma power supply 306, the substrate temperature controller 366, and the wafer bias voltage power supply 316.

The plasma power supply 306 and the wafer bias voltage power supply 316 may be configured to operate at specific radio frequencies such as 13.56 MHz, 27 MHz, 2 MHz, 1 MHz, 400 kHz, or combinations thereof. Plasma power supply 306 and wafer bias voltage power supply 316 may be appropriately sized to supply a range of powers in order to achieve desired process performance. For example, in one embodiment, the plasma power supply 306 may supply the power in a range of 50 to 5000 Watts, and the wafer bias voltage power supply 316 may supply a bias voltage in a range of 20 to 2000 V. In addition, the TCP coil 310 and/or the electrode 320 may be comprised of two or more sub-coils or sub-electrodes. The two or more sub-coils or sub-electrodes may be powered by a single power supply or powered by multiple power supplies.

As shown in FIG. 3, the plasma processing system 300 further includes a gas source 330. The gas source 330 provides gas or remote plasma to a feed 336 in the form of a nozzle. The process gases and by-products are removed from the plasma processing chamber 304 via a pressure control valve 342 and a pump 344. The pressure control valve 342 and the pump 344 also serve to maintain a particular pressure within the plasma processing chamber 304. The gas source 330 is controlled by the controller 324. A Kiyo® by Lam Research Corp. of Fremont, Calif., may be used to practice an embodiment.

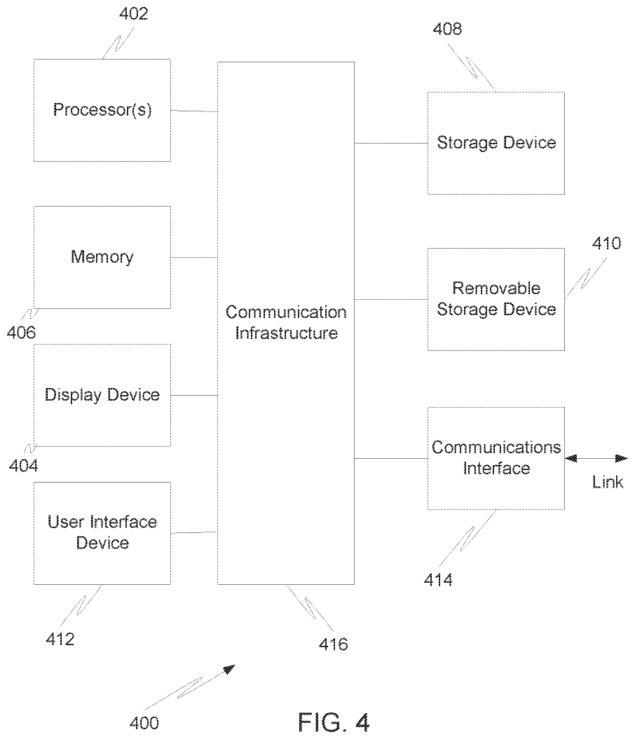

FIG. 4 is a high level block diagram showing a computer system 400. The computer system 400 is suitable for implementing a controller 324 used in embodiments. The computer system may have many physical forms ranging from an integrated circuit, a printed circuit board, and a small handheld device, up to a huge supercomputer. The computer system 400 includes one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link. The system may also include a communications infrastructure 416 (e.g., a communications bus, cross-over bar, or network) connected to the aforementioned devices/modules.

Information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network, or might output information to the network in the course of performing the above-described method steps. Furthermore, method embodiments may execute solely upon the processors or may execute over a network, such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory, and shall not be construed to cover transitory subject matter, such as carrier waves or signals. Examples of computer code include machine code, such as one produced by a compiler, and files containing higher level code that are executed by a computer using an interpreter. Computer readable media may also be computer code transmitted by a computer data signal embodied in a carrier wave and representing a sequence of instructions that are executable by a processor.

In this embodiment, the pre-coat may be formed on the chamber walls 362, the power window 312, the feed 336, the electrostatic chuck, and liners within the plasma reactor 302.

While this disclosure has been described in terms of several embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A method for processing one or more substrate in a plasma processing chamber, the method comprising a plurality of cycles, wherein each cycle comprises:
a) providing a pre-coat process, wherein the pre-coat process comprises one or more cycles of:
depositing a silicon containing pre-coat layer; and
depositing a carbon containing pre-coat layer;
b) processing at least one substrate within the plasma processing chamber; and
c) cleaning the plasma processing chamber.

2. The method, as recited in claim 1, wherein the silicon containing pre-coat layer is a silicon oxide based pre-coat layer.

3. The method, as recited in claim 1, wherein the silicon containing pre-coat layer is carbon free.

4. The method, as recited in claim 1, wherein the carbon containing pre-coat layer is silicon free.

5. The method, as recited in claim 1, wherein the carbon containing pre-coat layer comprises at least one of a hydrofluorocarbon, a hydrocarbon, or fluorocarbon.

6. The method, as recited in claim 1, wherein the depositing the carbon containing pre-coat layer, comprises:
flowing a carbon containing deposition gas, comprising at least one of a hydrofluorocarbon, a hydrocarbon, or a fluorocarbon;
forming the carbon containing deposition gas into a plasma; and
stopping the flow of the carbon containing deposition gas.

7. The method, as recited in claim 1, wherein the depositing the silicon containing pre-coat layer, comprises:
flowing a silicon containing deposition gas;
forming the silicon containing deposition gas into a plasma; and
stopping the flow of the silicon containing deposition gas.

8. The method, as recited in claim 7, wherein the silicon containing deposition gas comprises a silicon containing component and an oxygen containing component.

9. The method, as recited in claim 1, wherein the depositing the carbon containing pre-coat layer is before the depositing the silicon containing pre-coat layer.

10. The method, as recited in claim 1, wherein the depositing the carbon containing pre-coat layer is after the depositing the silicon containing pre-coat layer.

11. The method, as recited in claim 1, wherein the depositing the carbon containing pre-coat layer and the depositing the silicon containing pre-coat layer are not simultaneous.

12. The method, as recited in claim 1, wherein the pre-coat process comprises at least two cycles of:
depositing a silicon containing pre-coat layer; and
depositing a carbon containing pre-coat layer.

13. The method, as recited in claim 1, wherein the processing at least one substrate within the plasma processing chamber processes at least two substrates within the plasma processing chamber.

14. The method, as recited in claim 1, wherein the plasma processing chamber comprises a metal body.

15. The method, as recited in claim 14, wherein the plasma processing chamber comprises a protective coating over the metal body.

16. The method, as recited in claim 1, wherein the plasma processing chamber comprises a stainless steel or aluminum body.

17. The method, as recited in claim 1, wherein the plasma processing chamber comprises an aluminum body.

18. The method, as recited in claim 17, wherein the plasma processing chamber further comprises a protective coating over the aluminum body.

19. The method, as recited in claim 18, wherein the protective coating comprises yttrium oxide.

20. A method for conditioning a semiconductor processing chamber for processing a substrate, wherein the conditioning is provided before the substrate is placed in the semiconductor processing chamber, wherein the method comprises:
providing a pre-coat process, wherein the pre-coat process comprises one or more cycles of:
depositing a silicon containing pre-coat layer; and
depositing a carbon containing pre-coat layer.

21. The method, as recited in claim 20, wherein the silicon containing pre-coat layer is a silicon oxide based pre-coat layer.

22. The method, as recited in claim 20, wherein the silicon containing pre-coat layer is carbon free.

23. The method, as recited in claim 20, wherein the carbon containing pre-coat layer is silicon free.

24. The method, as recited in claim 20, wherein the depositing the carbon containing pre-coat layer, comprises:
flowing a carbon containing deposition gas, comprising at least one of a hydrofluorocarbon, a hydrocarbon, or a fluorocarbon;
forming the carbon containing deposition gas into a plasma; and
stopping the flow of the carbon containing deposition gas.

25. The method, as recited in claim 20, wherein the depositing the silicon containing pre-coat layer, comprises:
flowing a silicon containing deposition gas;
forming the silicon containing deposition gas into a plasma; and
stopping the flow of the silicon containing deposition gas.

26. The method, as recited in claim 20, wherein the semiconductor processing chamber comprises a metal body.

27. The method, as recited in claim 26, wherein the semiconductor processing chamber comprises a protective coating over the metal body.

28. The method, as recited in claim 20, wherein the semiconductor processing chamber comprises a stainless steel or aluminum body.

29. The method, as recited in claim 20, wherein the semiconductor processing chamber comprises an aluminum body.

30. The method, as recited in claim 29, wherein the semiconductor processing chamber further comprises a protective coating over the aluminum body.

31. The method, as recited in claim 30, wherein the protective coating comprises yttrium oxide.
